(19) United States
(12) Patent Application Publication
(10) Pub. No.: US 2021/0126152 A1
(43) Pub. Date: Apr. 29, 2021

(54) LIGHT WAVELENGTH CONVERSION MEMBER AND METHOD FOR PRODUCING SAME, PHOTOVOLTAIC MODULE, AND SOLAR BATTERY

(71) Applicant: NIPPON STEEL CORPORATION, Tokyo (JP)

(72) Inventor: Shinji TOKUMARU, Tokyo (JP)

(73) Assignee: NIPPON STEEL CORPORATION, Tokyo (JP)

(21) Appl. No.: 16/617,386

(22) PCT Filed: Apr. 25, 2018
(86) PCT No.: PCT/JP2018/016892

§ 371 Date: Nov. 26, 2019

(51) Int. Cl. H01L 31/18; H01L 31/055

(52) U.S. Cl. CPC H01L 31/186; H01M 10/465; H01L 31/055

(57) ABSTRACT

A light wavelength conversion member in which silicon nanoparticles are dispersed having a higher photoluminescence intensity, a method of production of the same, a photovoltaic module, and a photovoltaic cell, in particular, a light wavelength conversion member comprised of a substrate on one surface of which is formed a silicon oxide film in which silicon nanoparticles of a size of 1 nm to 10 nm are dispersed, the silicon oxide film, when the silicon oxide film is measured by the electron spin resonance method, having a spin density in the range of g=1.998±0.001 of 1×10¹⁶/cm³ or less and a spin density in the range of g=2.003±0.001 of 3×10¹⁶/cm³ or less and having a photoluminescence quantum yield with respect to incident light of a wavelength of 300 nm to 500 nm of 15% or more.

### FIELD

The present invention relates to a light wavelength conversion member and a method for producing the same and to a solar battery module and solar battery using that light wavelength conversion member.

### BACKGROUND

In the past, as a material for light emitting diodes, GaAs or ZnSe and other Group III-V- or Group II-VI-based compound semiconductor materials have been used, but if these could be replaced with silicon, which already plays a major role in large-sized integrated circuits and other parts of the semiconductor industry, there would be numerous merits due to the abundance of the resource, low environmental toxicity, low cost, etc.

Starting from the 1990 discovery of emission of red light from porous silicon through the anodic oxidation of the surface of a monocrystalline wafer in a hydrofluoric acid aqueous solution (NPL 1), light emitting diodes using nanoscale sized silicon have been developed for various applications.

For example, it has been disclosed that due to the size effect of nanosizing silicon three-dimensionally, it is possible to emit fluorescence, that by changing the particle size, near ultraviolet to near infrared light is emitted, and that in the visible light region, blue, green, and red (three primary colors) can be formed (PTLs 1 and 2). Further, it has been disclosed to apply nanoparticle sized silicon particles (below, “silicon nanoparticles”) to semiconductor lasers or light emitting diodes (PTL 1), to backlights of liquid crystal displays due to the ability to emit white light (PTL 2), to wavelength conversion devices for solar light power generation modules (PTL 3), and to biolabels (PTL 4).

Note that, “nanoscale” is a range defined by the ISO as about 1 nm to 100 nm in TS27687. Further, “nanoparticles” are particles having nanoscale dimensions in all three of the dimensions in the three dimensions.

Furthermore, in recent years, research on using silicon microcrystalline particles as light emitting materials has been energetically pursued. Specifically, the method for using sputtering, CVD, ion implantation, or other means to alternately deposit a silicon nitride polycrystalline film and silicon microcrystalline particles to produce a light emitting material (PTL 5) and the method for dispersing silicon microcrystalline particles in a silicon carbide polycrystal in a dot manner to produce a light emitting material (PTL 6) have been disclosed. Still further, the method for using a planetary ball mill to pulverize silicon powder to obtain silicon nanoparticles (PTL 7), the method for firing a mixture containing a silicon source and carbon source and rapidly cooling the vapor produced at that time to obtain silicon nanoparticles (PTL 3), etc. have been disclosed.

On the other hand, when trying to use silicon nanoparticles as light emitting materials for light emitting diodes, it is necessary to improve the emission intensity and emission stability. Various technologies are being developed to answer such needs.

Specifically, the emission intensity of silicon nanoparticles depends on their particle size. Therefore, the method for firing laser light of a specific wavelength in an oxygen atmosphere at a silicon oxide film containing Si nanoparticles of a large particle size not contributing to light emission so as to oxidize the surface and control the particle size (PTL 1), the method for adjusting the amount of Si contained in an Si:SiO₂ film (PTL 8), the method for dissolving the silicon oxide film in which silicon nanoparticles are buried by a fluoric acid solution to obtain a fluoric acid aqueous solution in which silicon nanoparticles are dispersed, then centrifuging this to separate them (PTL 9), etc. have been disclosed. Further, it is known that the surface conditions of silicon nanoparticles also greatly contribute to the emission intensity or emission stability. The method for reducing the difference in heat expansion coefficients between the SiO₂ and the silicon nanoparticles buried inside the same to reduce the light emission due to defects at the interfaces (PTL 10), passivation by organic molecules (PTL 11), core/shell structures (PTL 12), and other improvements have been disclosed.

Further, in PTLs 10 and 13 in which technologies for producing silicon nanoparticles by sputtering are disclosed, it is disclosed to prescribe the target area ratios and ratio of film forming rates of the silicon and SiO₂, while in PTL 14, it is disclosed to change the high frequency power and gas pressure to thereby adjust the amounts of silicon atoms sputtered from the target material to control the crystal sizes or densities of the silicon nanoparticles and form different colors.

Furthermore, the technique of doping a silicon oxide film with P to reduce the difference in heat expansion coefficients between the silicon oxide film and silicon nanoparticles, reduce the defects at the interfaces, and improve the emission intensity has been disclosed (PTL 10), but the emission peak is limited to emission of about 885 nm.

Further, PTL 17 discloses to form an amorphous SiO_{X} film in which silicon atoms and oxygen atoms are mixed together, heat treat this in an inert gas to form the silicon atoms into 3.0 nm nano-silicon, and treat this in a fluoric acid aqueous solution then treat it by heat oxidation to thereby obtain nano-silicon light emitting diodes emitting any of the three primary colors of light.

The light emitting diode disclosed in PTL 17 utilizes light emission due to recombination of electrons “e” of the localized state near the bottom end of the conduction band near the nano-silicon surface and the holes “h” of the localized state present near the top end of the valence band. In this way, the light emitting diode disclosed in PTL 17 utilizes the fluorescence due to the localized states between bands. However, it does not utilize light emission due to recombination of electrons at the bottom end of the conduction band near the nano-silicon surface and holes at the top end of the valance band. For this reason, there is still room for improving the emission intensity in the light emitting diode disclosed in PTL 17.

PTL 18 discloses the method for producing nanoscale silicon particles having a high fluorescence emission intensity. The method of production disclosed in PTL 18 includes a process of making silicon disperse by sputtering in a silicon oxide film formed on the substrate. In this process, the direction of incidence of the sputtered particles from the target to the substrate surface is made to become 10° to 80° with respect to the normal of the substrate and the substrate temperature is made 300° C. or less to perform sputtering, then heat treatment is performed in a nonoxidizing atmosphere at 800° C. to 1350° C.

However, the method of production of PTL 18 does not disclose reducing the number of dangling bonds of silicon nanoparticles and, further, does not disclose preventing the formation of localized states between the valence band and conduction band.

### CITATION LIST

### Patent Literature

[PTL 1] Japanese Unexamined Patent Publication No. 9-83075
[PTL 2] Japanese Unexamined Patent Publication No. 2007-63378
[PTL 3] WO2012/60418A
[PTL 4] Japanese Unexamined Patent Publication No. 2009-280841
[PTL 5] Japanese Unexamined Patent Publication No. 11-310776
[PTL 6] Japanese Unexamined Patent Publication No. 2000-77710
[PTL 7] Japanese Unexamined Patent Publication No. 2011-213848
[PTL 8] Japanese Unexamined Patent Publication No. 2003-277740
[PTL 9] Japanese Unexamined Patent Publication No. 2010-254972
[PTL 10] Japanese Unexamined Patent Publication No. 2001-40348
[PTL 11] Japanese Unexamined Patent Publication No. 2010-205686
[PTL 12] Japanese Unexamined Patent Publication No. 2009-96954
[PTL 13] Japanese Unexamined Patent Publication No. 2004-83740
[PTL 14] Japanese Unexamined Patent Publication No. 2005-268337
[PTL 15] Japanese Unexamined Patent Publication No. 2001-14664
[PTL 16] Japanese Unexamined Patent Publication No. 2013-14806
[PTL 17] Japanese Unexamined Patent Publication No. 2004-296781
[PTL 18] Japanese Unexamined Patent Publication No. 2016-169416

### Non Patent Literature

[NPL 1] L. T. Canham, Appl. Phys. Lett., vol. 57, p. 1046 (1990)
[NPL 2] Applied Physics, vol. 70, No. 7 (2001), 852-856
[NPL 3] Proceeding of the School of Engineering of Tokai University, vol. 37, No. 2 (1999), 33-37
[NPL 4] ADVANCED FUNCTIONAL MATERIALS 22 (2012), 3223-3232

### SUMMARY

### Technical Problem

When applying silicon nanoparticles to light emitting diodes and other electronic devices, the silicon nanoparticles are required to have light emission spectra or light absorption spectra corresponding to the functions of the electronic devices they are applied to. However, the above art is just art for adjusting the amount of silicon buried in the silicon oxide film to control the size of silicon nanoparticles and cause the formation of color or art for reducing the difference of heat expansion coefficients between the silicon oxide film and silicon nanoparticles and reducing defects at the interfaces to improve the emission intensity at a certain specific wavelength. Therefore, in the above prior art, the function of increasing the emission intensity is insufficient. There are believed to be limits as a method for further improving the functions of the electronic devices.

An object of the present invention is to provide a light wavelength conversion member in which the silicon nanoparticles are dispersed having a higher emission intensity and method for producing the same, a photovoltaic module, and a solar battery.

### Solution to Problem

The inventors engaged in repeated intensive studies to solve the above problems and as a result discovered that by forming a silicon oxide film in which silicon is dispersed by sputtering, then heat treating the silicon oxide film in a nonoxidizing atmosphere and further heat treating the silicon oxide film in an oxygen-containing atmosphere, it is possible to obtain silicon nanoparticles having a sufficient emission intensity and thereby perfected the present invention.

The object of the present invention is achieved by the following constitutions:

(1) A light wavelength conversion member comprising a substrate and a silicon oxide film in which silicon nanoparticles are dispersed, wherein the silicon oxide film is superposed on one surface of the substrate, directly or through another layer, wherein the silicon oxide film has a spin density of 1×10¹⁶/cm³ or less at an electron spin resonance signal of g-value of 1.9980±0.0010 and a spin density of 3×10¹⁶/cm³ or less at g-value of 2.0030±0.0010 when measuring the silicon oxide film by way of the electron spin resonance method.
(2) The light wavelength conversion member according to (1), wherein the silicon oxide film in which silicon nanoparticles are dispersed has an arithmetic average roughness Ra of 5 nm to 50 nm.
(3) The light wavelength conversion member according to (1) or (2), wherein the silicon oxide film is superposed over a rough layer formed on one surface of the substrate and the rough layer contains at least one of oxygen and nitrogen, contains silicon, and has a thickness of 0.1 μm to 0.3 μm.
(4) A solar battery including the light wavelength conversion member according to any one of (1) to (3) placed on a light receiving surface side.
(5) A photovoltaic module including the light wavelength conversion member according to any one of (1) to (3) placed on a light receiving surface side.
(6) A method for producing a light wavelength conversion member comprising the steps of: forming a silicon oxide film on the substrate by way of sputtering, the temperature of the substrate being made to be 300° C. or less, dispersing the silicon in the silicon oxide film, then heat treating the silicon oxide film in a nonoxidizing atmosphere at the temperature range of from 800° C. to 1150° C., and then heat treating the silicon oxide film in an oxygen-containing atmosphere at the temperature range of from 500° C. to 1000° C.
(7) The method for producing a light wavelength conversion member according to (6), wherein in the step of sputtering, an incidence angle of sputtered particles from a target with respect to the substrate surface is made to be 10° to 80° with respect to the normal of the substrate.
(8) The method for producing a light wavelength conversion member according to (6) or (7), wherein in the step of sputtering, the substrate surface is inclined by 10° to 80° with respect to a directly facing target surface to control an incidence direction of sputtered particles from the target.
(9) The method for producing a light wavelength conversion member according to any one of (6) to (8), wherein a target in which silicon and silicon oxide are mixed in a sputtered area is sputtered to disperse silicon in the silicon oxide film.
(10) The method for producing a light wavelength conversion member according to any one of (7) to (9), wherein an incidence direction of sputtered particles from a target consisting silicon oxide or a target in which silicon and silicon oxide are mixed in a sputtered area is made to be 10° to 80° with respect to a normal of the substrate, wherein a temperature of the substrate is made to be 300° C. or less, and wherein the step of sputtering is conducted in an atmosphere containing at least one of oxygen and nitrogen to deposit a rough layer of a 0.1 μm to 0.3 μm thickness, then the silicon oxide film is formed on the substrate.
(11) The method for producing a light wavelength conversion member according to (10), wherein the rough layer is deposited in the atmosphere containing argon gas and at least one of oxygen and nitrogen, wherein the total pressure of the atmosphere is 0.3 Pa to 1.5 Pa, and the total of the oxygen partial pressure and nitrogen partial pressure is 10% to 50% with respect to the total pressure of the atmosphere.
(12) The method for producing a light wavelength conversion member according to any one of (6) to (11), wherein the step of heat treating in the oxygen-containing atmosphere is carried out in an oxygen-containing atmosphere containing a concentration of 1 vol % to 50 vol % of oxygen.

### Advantageous Effects of Invention

According to the present invention, it is possible to manufacture a light wavelength conversion member with a higher emission intensity easily and relatively inexpensively without causing a drop in productivity. Therefore, by using the light wavelength conversion member of the present invention, it is possible to raise the efficiency of generation of electric power of a photovoltaic module or solar battery corresponding to the light absorption spectrum of the semiconductor forming the solar battery. Further, according to the present invention, no organic compound is used for the light wavelength conversion member, so deterioration of the light wavelength conversion member due to ultraviolet rays or other short wavelength light will not affect the service life of the solar battery module.

### BRIEF DESCRIPTION OF DRAWINGS

FIG. 1 is a schematic view of a first embodiment of a light wavelength conversion member according to the present invention and a process of producing the same.

FIG. 2 is a schematic view of a second embodiment of a light wavelength conversion member according to the present invention and a process of producing the same.

FIGS. 3A and 3B are schematic views of a method for manufacturing a third embodiment of a light wavelength conversion member according to the present invention, wherein FIG. 3A shows an outline of a process of deposition of a rough layer 3b while FIG. 3B shows an outline of a process of superposing a silicon oxide film 3.

FIGS. 4A and 4B respectively show embodiments of light emitting diodes using the light wavelength conversion member according to the present invention.

FIG. 5 shows an embodiment of a photovoltaic module using a light wavelength conversion member according to the present invention.

FIG. 6 shows an embodiment of a solar battery using a light wavelength conversion member according to the present invention.

FIG. 7 shows photoluminescence (PL) spectra of light wavelength conversion members of invention examples and comparative examples.

FIG. 8 is a view explaining energy levels of a light wavelength conversion member according to the present invention and a conventional light wavelength conversion member.

FIG. 9 is a view showing converted solar spectrum and spectral response of a photovoltaic cell in the case of using a light wavelength conversion member according to the present invention.

FIG. 10 is a transmission electron micrograph of a cross section of a silicon oxide film of Sample No. 37 (invention example).

### DESCRIPTION OF EMBODIMENTS

In the light wavelength conversion member of the present invention, a silicon oxide film is deposited on one surface of a substrate and has silicon nanoparticles dispersed in it. There are extremely few dangling bonds present at the interfaces of the silicon nanoparticles and the silicon oxide outside thereof and there are extremely few defects near the surfaces of the silicon nanoparticles.

Here, “there are extremely few dangling bonds present at the interfaces of the silicon nanoparticles and the silicon oxide outside of them” means that when using a standard electron spin resonance apparatus to measure the density of spins (g-value which is an electron spin resonance signal is in a range of 2.0030±0.0010; P_{b}-center) due to electrons of dangling bonds present at the interfaces of the silicon nanoparticles and the silicon oxide outside of them, the spin density is 3×10¹⁶/cm³ or less. Further, “there is no localized state between the bands” means that when using a standard electron spin resonance apparatus to measure the density of spins (g-value which is an electron spin resonance signal is in a range of 1.9980±0.0010; P_{ce}-center) due to conductive electrons inside the silicon nanoparticles, the spin density is 1×10¹⁶/cm³ or less.

Even in a state where the nano-silicon and silicon oxide are completely separated, the P_{b}-center due to the dangling bonds present at the interfaces of the silicon nanoparticles and the silicon oxide outside them is non-radiative recombination center, so the number is preferably as small as possible. In PTL 17, the dangling bonds are treated by fluoric acid to terminate them by hydrogen and cause the emission intensity to rise.

Further, NPL 3 discloses that when forming an amorphous SiOx film of silicon atoms and oxygen atoms mixed together and heat treating it in an Ar atmosphere at 900° C., the spin density of P_{b} center was 4.0×10¹⁶/cm³, but at 1100° C., rises to 2.4×10¹⁷/cm³. However, NPL 3 discloses that due to treatment by fluoric acid, the signal intensity falls to the lower limit of detection and the emission intensity increases.

In the method of manufacture disclosed in PTL 17 and NPL 3, a fluoric acid aqueous solution is used for treatment to expose the nano-silicon on the sample surface and oxidize the nano-silicon, therefore, mismatching parts may arise. For this reason, it is guessed that localized states remain between bands in the nano-silicon disclosed in PTL 17 and NPL 3.

Furthermore, in NPL 4, it is disclosed that when heat treating the silicon oxide film in which silicon is dispersed in an inert gas (N₂) at 1100° C., then heat treating it in hydrogen gas at 450° C., the dangling bonds is terminated by hydrogen and that the fluorescence quantum yield is improved up to 13% after hydrogen heat treatment compared to the 4% before hydrogen heat treatment.

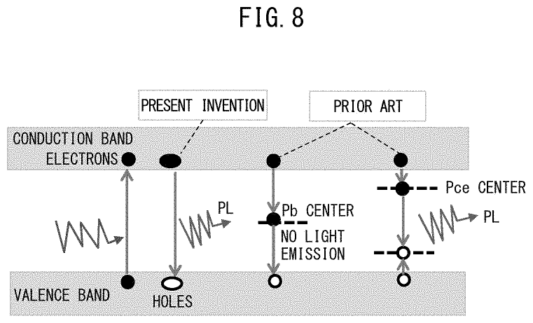

On the other hand, it is disclosed that when forming an amorphous SiOx film comprising silicon atoms and oxygen atoms mixed together and heat treating this in an Ar atmosphere at 900° C., the spin density at P_{ce}-center was 1.5×10¹⁶/cm³, while the spin density at P_{ce}-center rises to 4.0×10¹⁶/cm³ by virtue of heat treatment at 1100° C. and that when using fluoric acid to terminate bonds by hydrogen, the spin density further rises (NPL 2). In view of these facts, it is generally believed that the substantial fraction of light emission is predominantly occupied by light emission caused in the process of electrons trapped at localized states between bands in silicon nanoparticles recombinating with holes (prior art of FIG. 8). However, light emission caused by electrons having spins of P_{ce}-center is not light emission due to recombination of electrons at the bottom end of the conduction band and holes at the top end of the valance band near the nano-silicon surface.

As opposed to this, in the light wavelength conversion member according to the present invention, the silicon nanoparticles in the light wavelength conversion member are oxidized without allowing them to be exposed from the silicon oxide film. Therefore, the interfaces between the silicon nanoparticles and silicon oxide film is slightly caused to be oxidized, thereby, the dangling bonds at the interfaces are eliminated and the defects causing localized states between bands near the surfaces of the silicon nanoparticles due to rearrangement of silicon atoms near the interfaces are probably decreased. For this reason, the silicon nanoparticles of the light wavelength conversion member according to the present invention are extremely low in localized states between the bands.

In this way, in the light wavelength conversion member according to the present invention, the spin density of the P_{b}-center and the spin density of the P_{ce}-center are extremely small. Further, the light emission by the light wavelength conversion member according to the present invention, as shown in FIG. 8 by “the present invention”, occurs due to recombination of electrons at the bottom end of the conduction band and holes at the top end of the valance band near the nano-silicon surface.

As shown in FIG. 8, the photoluminescence (PL) intensity in the light wavelength conversion member according to the present invention is larger compared with the prior art. The light wavelength conversion member according to the present invention does not contain any non-radiative recombination centers (Pb-center). Further, the light emission in the light wavelength conversion member according to the present invention is not a transition between localized states (Pce-center) wherein the photoluminescence intensity ends up becoming smaller due to the probability of transition of electrons or the distance between electrons and holes. Therefore, the photoluminescence quantum yield with respect to incident light of a wavelength of 300 nm to 500 nm is 15% or more.

Next, embodiments of the light wavelength conversion member according to the present invention and the method for producing the same will be explained specifically.

### First Embodiment

The light wavelength conversion member of the first embodiment is provided with a silicon oxide film in which silicon nanoparticles are dispersed. The silicon oxide film is prepared under the following sputtering conditions:

Conditions of Sputtering

A silicon oxide film is formed on a substrate made of mainly SiO₂ or other dielectric substrate. To control the amount of silicon to be introduced into the silicon oxide film, a target comprising silicon and silicon oxide mixed together in the sputtered region may be used to enable both silicon and silicon oxide to become sputtered particles. By sputtering in this way, the ratio of mixture of silicon can be adjusted.

As the target where silicon and silicon oxide are mixed in the sputtered region, silicon oxide (SiOx(0.5≤x≤2)) may be used. To control the amount of silicon to be introduced into the silicon oxide film, silicon chips may be placed on the target. Further, other than the practice of arranging silicon chips on silicon oxide, it is possible to use a composite target of silicon and silicon oxide instead of a target of silicon oxide. Further, the form of the composite of silicon and silicon oxide at the composite target is not particularly limited. For example, the composite target may be a mixture or composite of particles of silicon and particles of silicon oxide.

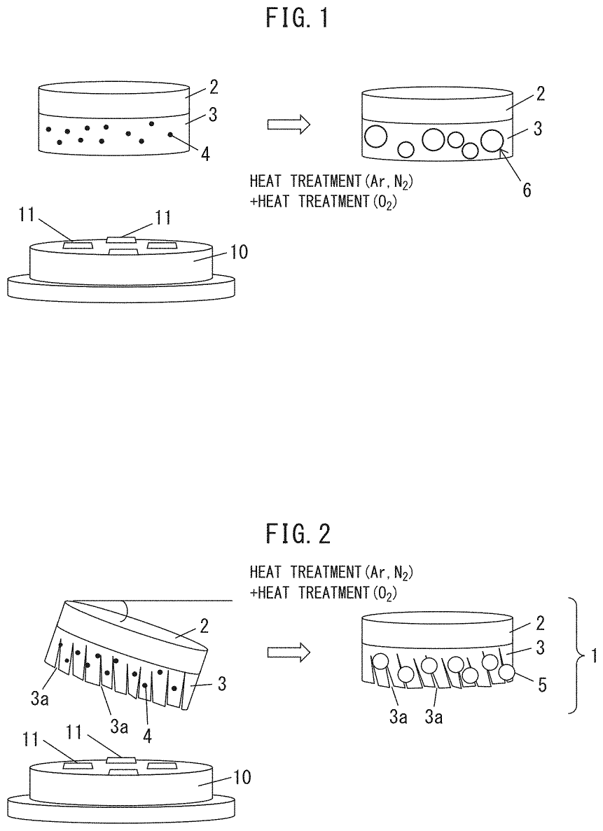

FIG. 1 is a schematic view of a light wavelength conversion member 1 of a first embodiment according to the present invention and a method for producing the same. In this embodiment, SiO₂ is used as the target 10 for forming the silicon oxide film 3 by way of sputtering.

As shown in FIG. 1, by placing silicon chips 11 at a plurality of locations on the target 10 and co-sputtering deposition on the substrate 2, silicon 4 becomes present in a state dispersed in the silicon oxide film 3. The silicon 4 consists of only silicon atoms present in the silicon oxide film in a state not bonded with oxygen atoms.

If the mobility of the sputtered particles deposited on the growing film becomes too large, the pores or voids end up being buried by the sputtered particles, and therefore the substrate temperature has to be made 300° C. or less. When performing the sputtering at room temperature without heating the substrate, the substrate temperature is caused to rise because the substrate is exposed to plasma. While differing depending on the target applied power, the gas pressure, and other sputtering conditions, the temperature never becomes 300° C. or more.

In the sputtering, argon or another inert gas is used to form a thin film of the same components as the components contained in the target. For example, in FIG. 1, as the sputtering gas, argon is used and a thin film including both the components of the target 10 and the silicon component of the silicon chips is formed. In a first embodiment, as the substrate 2, an SiO₂ substrate is used. Further, in later explained embodiments as well, an SiO₂ substrate is used as the substrate 2, but instead of an SiO₂ substrate, it is also possible to apply a glass substrate containing Al₂O₃, CaO, etc. as the substrate 2. The inert gas may include nitrogen gas or a nitrogen compound gas up to 2 vol % or less. However, when the nitrogen gas or nitrogen compound gas is contained in the inert gas in over 2 vol %, the silicon is caused to be nitrided, and the nitrogen contained in the film suppresses diffusion of silicon in the heat treatment after sputtering deposition and obstructs the aggregating of silicon. As a result, there is a possibility of the photoluminescence intensity being lowered, so this is not preferable.

In addition to the above method, for example, it is also possible to use a target consisting of silicon and a target consisting of silicon oxide (SiOx(0.5≤x≤2)) and alternately move the substrates above the targets. Alternatively, it is also possible to control the positional relationship of the silicon target and the silicon oxide target with the substrate surface so that sputtered particles from the two targets are superposed in the substrate surface. These methods may be used to form a multilayer film of a silicon film and silicon oxide film or a mixed film of silicon and silicon oxide. A silicon film 3 in which silicon 4 is dispersed may be produced by heat treating the multilayer film or the mixed film.

Conditions of Heat Treatment After Sputtering Deposition

The silicon oxide film formed by the above method is first heat treated in a nonoxidizing gas atmosphere. Due to this heat treatment in a nonoxidizing gas atmosphere, silicon nanoparticles 6 are formed in the silicon oxide film.

As the nonoxidizing gas, argon gas is mainly used, but it may also be nitrogen gas or a nitrogen compound gas.

The lower limit of the heat treatment temperature is made 800° C. or more so as to form the silicon contained in the silicon oxide film to nanoparticles in a relatively short time. On the other hand, the upper limit of the heat treatment temperature is made 1150° C. or less in order to prevent silicon oxide and silicon from reacting and changing to silicon monoxide and prevent the silicon from ending up being consumed. The heat treatment time is preferably 10 minutes to 120 minutes, but the emission wavelength depends on the size of the silicon nanoparticles, so it is necessary to regulate the heat treatment temperature and heat treatment time in accordance with the amount of silicon contained in the silicon oxide film and the substrate surface roughness.

After the heat treatment in the nonoxidizing atmosphere, the silicon oxide film is heat treated in an oxygen-containing atmosphere at 500° C. to 1000° C. Silicon easily oxidizes. In particular, silicon nanoparticles have a large specific surface area, so end up being consumed with even slight oxidation. Therefore, the oxygen concentration in the oxygen-containing atmosphere is made 1 to 50 vol % and the balance is made the nonoxidizing gas component and unavoidable impurity gas components.

By virtue of the above-mentioned heat treatment in an oxygen-containing atmosphere, it is possible to greatly reduce the dangling bonds at the interfaces of the silicon nanoparticles and the silicon oxide outside them (P_{b}-center) as explained above and eliminate the localized states between bands.

The heat treatment time is preferably 10 minutes to 120 minutes. When less than 10 minutes, the effect becomes insufficient, while even if over 120 minutes, the effect cannot be further enhanced and the productivity ends up being lowered. Further, when the oxygen concentration is less than 1 vol %, sometimes the effect of reducing the dangling bonds of the P_{b}-center or the effect of reducing defects near the surfaces of silicon nanoparticles of the Pce-center cannot be sufficiently obtained. Further, when the oxygen concentration exceeds 50 vol %, defects are formed at the surfaces of the silicon nanoparticles at the interfaces with the silicon oxide and the effect of reducing the dangling bonds of P_{b}-center sometimes cannot be sufficiently obtained.

Further, the sizes of the silicon particles are measured by a transmission electron microscope (TEM) image of the thin film block formed from a sample heat-treated in the oxygen-containing atmosphere using a focused ion beam (FIB) system.

### Second Embodiment

The light wavelength conversion member of the second embodiment comprises a substrate provided with a silicon oxide film in which a suitable amount of pores or voids is introduced and controlled in roughness of the surface of the silicon oxide film so that the arithmetic average roughness Ra of the surface of the silicon oxide film becomes 5 nm to 50 nm. The light wavelength conversion member of the second embodiment is fabricated under the following manufacturing conditions. Further, the light wavelength conversion member of the second embodiment is produced by the method comprising process of radiating sputtered particles to a substrate at an inclination to form a silicon oxide film, the process of heat treating the silicon oxide film in a nonoxidizing gas atmosphere, and the process of heat treating the silicon oxide film in an oxygen-containing atmosphere after heat treating it in the nonoxidizing atmosphere. As conditions when performing these processes, it is possible to employ conditions the same as the first embodiment except for the conditions considered required for securing suitable pores or voids in the silicon oxide film.

Process for Treatment of Substrate for Making Silicon Oxide Film Surface Arithmetic Average Roughness Ra of 5 nm to 50 nm

The roughness of the surface of the silicon oxide film formed on the substrate surface reflects the surface roughness of the substrate. The film formed by sputtering is a thin, uniform one of several μm or less in thickness, so by adjusting the substrate surface roughness, it is possible to make the arithmetic average roughness Ra of the surface of the silicon oxide film 5 nm to 50 nm.

The surface roughness of the substrate can be made a predetermined surface roughness by adjustment in the process of polishing the surface or by wet blasting spraying water containing a polishing agent of several μm size at a mirror finished substrate. However, in the present invention, the arithmetic average roughness (Ra) is the roughness defined based on JIS B 0601:2001.

That is, in the present invention, the arithmetic average roughness (Ra) means the value which is obtained by a method comprising the steps of sampling just a reference length (l) from the roughness profile in the direction of the mean line thereof, setting an X-axis in the direction of the mean line of that sampled part, setting a Y-axis in the direction of the vertical multiple, expressing the roughness profile by the following equation (1), and specifying the value of the roughness profile by the following equation (2) (JIS B 0601:2001).

$$\begin{matrix}[ Equation 1 ] & \\ y = f ( x ) & ( 1 ) \\ Ra = \frac{1}{ℓ} {\int }_{0}^{ℓ} \vert f ( x ) \vert dx & ( 2 )\end{matrix}$$

The arithmetic average roughness (Ra) is measured using atomic force microscopy (AFM). The arithmetic average roughness is measured under the measurement conditions based on JIS R 1683:2007. This is performed by measuring five locations of the four corners and center of a 10 mm square region near the center of a sample and calculating the average of the same.

Process for Forming Silicon Oxide Film

To secure suitable pores and voids in the silicon oxide film, the average incidence direction of the sputtered particles from the target with respect to the substrate surface is made 10° to 80° with respect to the normal of the substrate. When less than 10°, sufficient pores or voids cannot be formed. On the other hand, when over 80°, the voids become too large, part of the silicon particles become enlarged at the time of heat treatment, or the silicon ends up not being covered by silicon oxide in state, so as a result the photoluminescence intensity does not become higher.

As shown in FIG. 2, by impinging the sputtered particles on the substrate at an oblique incidence of the above-mentioned angle, the incidence of the sputtered particles flying to the substrate is shadowed by the sputtered particles already deposited on the substrate themselves. The shadowed area cannot be covered by sputtered particles. Silicon 4 becomes present in a state dispersed in the silicon oxide film 3 and pores and voids 3a are sufficiently formed due to the self-shadowing effect.

The silicon 4 consists of only silicon atoms which are present in the silicon oxide film in a state not bonded with the oxygen atoms. Due to the pores or voids, at the time of the later explained heat treatment, the silicon 4 aggregates and silicon nanoparticles 5 are formed. At this time, they become uniform size structures. Further, the number of dangling bonds at the interfaces of the silicon oxide film 3 and silicon nanoparticles 5 and the number of defects of the surfaces of the silicon nanoparticles are remarkably reduced at the time of the later explained heat treatment in a nonoxidizing gas atmosphere.

The method for incling the substrate from the directly facing target surface by 10° to 80° is easy and is preferable in terms of productivity. Further, as other methods, there are the method for placing the substrate at a position offset in parallel from the position directly facing the target (PTL 16) and the method for placing a collimator (mask having through holes) between the target and substrate (PTL 15). Any of these methods is acceptable.

When making sputtered particles impinge at an oblique incidence, the formation of pores and voids by the shadowing effect is affected by the roughness of the substrate surface. As explained above, even if the surface is completely flat, pores and voids are formed by the self-shadowing effect. However, if the substrate surface roughness is adjusted so that the arithmetic average roughness of the surface of the silicon oxide film becomes 5 nm to 50 nm, this is preferable for realizing uniformity of silicon nanoparticles and the maximum value of the photoluminescence intensity of the photoluminescence spectrum can be improved. Further, from the viewpoint of improving the quantum yield, the arithmetic average roughness of the surface of the silicon oxide film is more preferably 7 nm to 30 nm. When over 50 nm, sometimes large voids are formed, silicon flows out into the voids at the time of heat treatment, and the silicon particles become enlarged. When the silicon particles end up exceeding 5 nm in size, good light emission cannot be obtained (PTL 1). Alternatively, when the silicon particles are exposed from the silicon oxide film, heat treatment of the exposed surfaces of the silicon particles causes defects and other mismatched portions. For this reason, dangling bonds present at the interfaces of the silicon nanoparticles and the silicon oxide outside them will increase and the silicon particles will end up not emitting light.

In the second embodiment, the silicon oxide film contains numerous voids. As a result, the size of the silicon nanoparticles becomes uniform and further the quality of crystal is improved, so the photoluminescence intensity becomes greater.

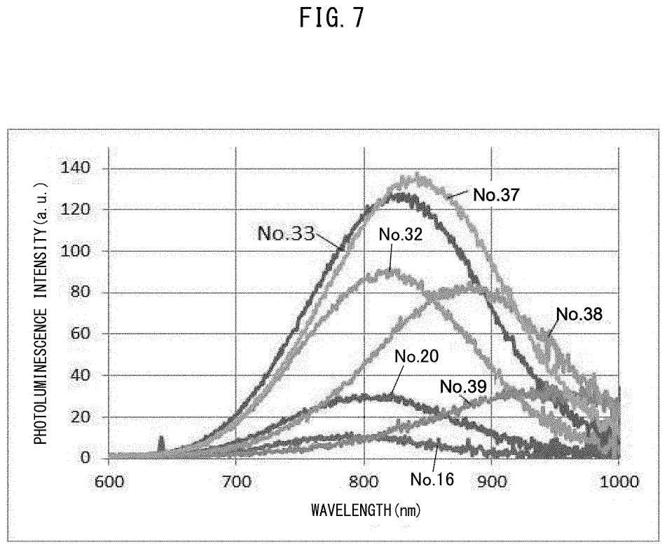

The fluorescence wavelength is sensitive to the size of the silicon nanoparticles, so the size of silicon nanoparticles can be estimated from the photoluminescence (PL) spectrum of the emission. For example, a high emission intensity at 800 nm means a large number of silicon nanoparticles of sizes corresponding to 800 nm. The photoluminescence spectrum of the sample shown in FIG. 7 is 650 nm to 1000 nm. Based on the descriptions in PTLs 1 and 9 etc., the size of the silicon nanoparticles in the silicon oxide film of the sample shown in FIG. 7 can be estimated to be 2.5 nm to 5 nm in range.

### Third Embodiment

The light wavelength conversion member of a third embodiment includes a smooth substrate, a rough layer deposited on the surface of the substrate and containing at least one of oxygen and nitrogen, and a silicon oxide film in which silicon nanoparticles are dispersed superposed over the rough layer.

In the second embodiment, a substrate with a surface conditioned to secure suitable pores and voids in the silicon oxide film was used. The substrate was treated by the above method to form roughness on the surface. However, it is also possible to form a rough layer on a smooth substrate.

In the third embodiment, a rough layer consisting of silicon oxide (SiOx (0.5≤x≤2)) is formed on a smooth substrate so that the arithmetic average roughness Ra of the surface of the silicon oxide film in which the silicon nanoparticles are dispersed becomes 5 nm to 50 nm, preferably 7 nm to 30 nm.

The light wavelength conversion member of the third embodiment is produced by a process of forming a rough layer on the surface of the substrate, a process of making sputtered particles impinge the substrate at an oblique incidence to form a silicon oxide film, a process of heat treating the silicon oxide film in a nonoxidizing gas atmosphere, and a process of heat treating the silicon oxide film in an oxygen-containing atmosphere after the heat treatment in the nonoxidizing atmosphere.

Process of Forming Rough Layer on Surface of Substrate

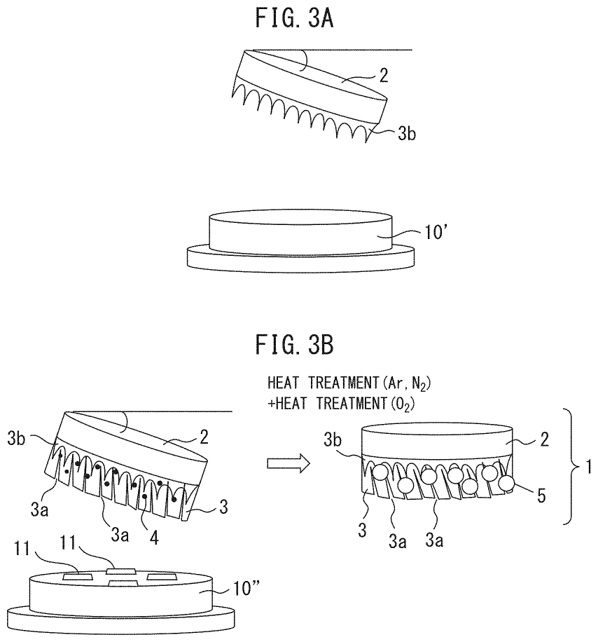

As shown in FIG. 3A, a first target 10′ (silicon oxide (SiOx (0.5≤x≤2))) is sputtered in an atmosphere containing at least one of oxygen and nitrogen and the incident angle of the sputtered particles is made a direction of 10° to 80° with respect to the normal of the SiO₂ substrate to thereby form a rough layer 3b containing at least one of oxygen and nitrogen and containing silicon. When the average incident angle of the sputtered particles from the target to the substrate surface is less than 10° with respect to the normal of the substrate, a sufficient surface roughness cannot be secured. When over 80°, the film forming speed ends up greatly falling. Further, the temperature of the SiO₂ substrate is made 300° C. or less.

Further, the target when depositing the rough layer may be a target consisting of silicon oxide. Silicon chips may also be placed on the target of silicon oxide in the structure. Further, a composite target of silicon and silicon oxide as explained above may also be used. However, the atmosphere wherein the rough layer is deposited by virtue of sputtering must contain at least one of oxygen and nitrogen. Further, the atmosphere wherein the rough layer is deposited by virtue of sputtering preferably contains argon gas. The total pressure preferably is made 0.3 Pa to 1.5 Pa, and the total of the oxygen partial pressure and nitrogen partial pressure preferably is made 10% to 50% with respect to the total pressure of the atmosphere.

When forming a rough layer by sputtering, it is necessary to establish an environment in which the self-shadowing effect becomes larger, that is, film forming conditions where the sputtered particles impinge the substrate from the same direction. Since the sputtered particles are scattered by collision with the argon gas, they impinge the substrate at various angles, and therefore the pressure of the argon gas is made 1.5 Pa or less. Conversely, when the pressure becomes too small, the discharge stability and film thickness uniformity will fall, and therefore the pressure has to be made 0.3 Pa or more.

On the other hand, the sputtered particles which have not scattered due to the argon gas reach the substrate while holding a large energy, so the mobility is high and the self-shadowing effect ends up being reduced. Therefore, by virtue of adding oxygen or nitrogen into the sputtering atmosphere, the atoms or molecules of at least one of the oxygen and nitrogen adsorbed on the substrate can trap the sputtered particles which reached the substrate and reduce the mobility thereof. When the total of the oxygen partial pressure and the nitrogen partial pressure is less than 10% of the total pressure, the amount for trapping the sputtered particles becomes insufficient. However, when over 50%, this becomes excessive and ends up inviting a large fall in film deposition rate.

Further, the rough layer is deposited to a thickness of 0.1 μm to 0.3 μm. When the thickness of the rough layer is less than 0.1 μm, it is not possible to form a rough surface for forming sufficient pores or voids inside the silicon oxide film. Further, when the thickness of the rough layer exceeds 0.3 μm, large voids are formed. The voids in the silicon oxide film in which these silicon particles are dispersed and which is formed on the rough layer also become thicker, so at the time of heat treatment, silicon flows out to the voids and the silicon nanoparticles end up becoming enlarged or the state no longer becomes one where the nanoparticles are buried in the silicon oxide. Therefore, when the thickness of the rough layer exceeds 0.3 μm, the dangling bonds present at the interfaces of the silicon nanoparticles and the silicon oxide outside of them increase and the silicon particles end up no longer emitting light.

Further, in the process for forming the rough layer, besides sputtering, the vacuum evaporation method using silicon or silicon oxide as the evaporation source and introducing oxygen gas or nitrogen gas to form a film or the ion plating method may also be used.

Conditions for Formation of Silicon Oxide Film on Rough Film

After depositing the rough film, a silicon oxide film is formed on the rough layer under the same conditions as the second embodiment. As shown in FIG. 3B, silicon chips 11 are arranged on the second target 10″ (silicon oxide (SiOx(0.5≤x≤2))) or at a plurality of locations on the second target 10″ and the substrate 2 is sputtered from the above-mentioned incidence direction to thereby establish the presence in the silicon oxide film 3 of clustered silicon or particles 4 consisting of silicon atoms (below, referred to as “Si particles”) in a dispersed state and sufficiently form pores or voids 3a. The Si particles 4 consists of only silicon atoms present in the silicon oxide film in a state not coupled with oxygen atoms.

Conditions of Heat Treatment After Sputtering

The silicon oxide film formed by the above method is heat treated in a nonoxidizing gas atmosphere under the same conditions as the first embodiment or second embodiment, then is heat treated in an oxygen-containing atmosphere. In the third embodiment, due to the pores or voids, when the Si particles 4 aggregate whereby silicon nanoparticles 5 are formed by heat treatment in the nonoxidizing gas atmosphere, the sizes are made uniform. Furthermore, by performing heat treatment in an oxygen-containing atmosphere, the core of the silicon nanoparticle becomes a crystal with extremely few localized states, and carrier recombination becomes hard to occur at the interfaces of the silicon nanoparticles/silicon oxide film. Further, by performing heat treatment, there is the merit that the surface of the silicon oxide film is smoothed.

### Embodiment of Light Emitting Diode According to Present Invention

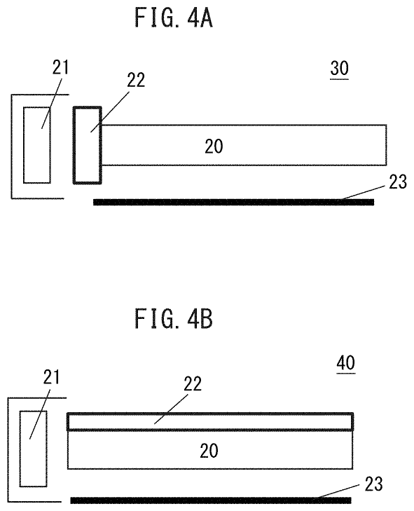

The light wavelength conversion member of the present invention is structured including a silicon oxide film in which silicon nanoparticles are dispersed and a substrate on which the silicon oxide film is formed. The light wavelength conversion member of the present invention can convert light of a short wavelength to a long wavelength, so can superpose blue light and that light converted to red and green light to thereby synthesize white light, so the light wavelength conversion member of the present invention can be used as a light emitter of a light emitting diode. For example, as shown in FIGS. 4A and 4B, it is also possible to use a blue LED 21 as the light source and use the light wavelength conversion member of the present invention as the light guide plate 20 or light emitter 22 and thereby form a white backlight 30 of a liquid crystal etc. Further, the backlight 30 of FIG. 4A is an on-edge type, while the backlight 40 of FIG. 4B is a surface mounted type. The reflector 23 is preferably formed so as to reflect light in a certain direction at a higher reflectance.

### Embodiment of Solar Battery Module According to Present Invention

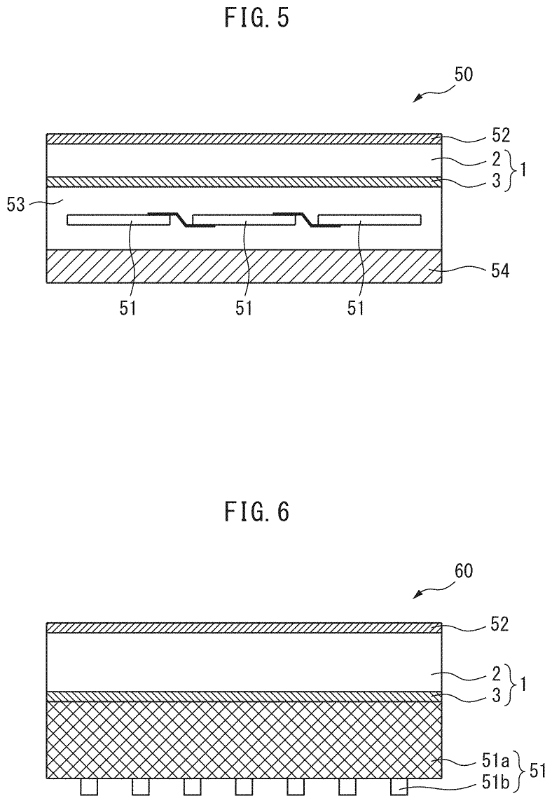

FIG. 5 shows an embodiment of a photovoltaic module using the light wavelength conversion member 1 of the present invention. This photovoltaic module 50 is provided with a light wavelength conversion member 1 consisting of a glass plate 2 as a transparent substrate and a silicon oxide film 3 formed on the glass plate 2 and having the silicon nanoparticles 5 dispersed therein. The light wavelength conversion member 1 is arranged at the side of the photovoltaic cell 51 sealed inside a sealing material 53 where sunlight irradiate so that the silicon oxide film 3 contacts it. On the glass plate 2, an antireflection film 52 is coated as an outermost layer at the side of the photovoltaic module irradiated by sunlight. On the other hand, at the other side of the sealing material 53, a back side protection material 54 is provided. Further, as the glass substrate, a substrate consisting of only SiO₂ or another silicon oxide or a glass substrate containing the silicon oxide may be used.

### Embodiment of Solar Battery According to Present Invention

FIG. 6 shows an embodiment of a solar battery using the light wavelength conversion member 1 of the present invention. The solar battery 60 of this embodiment is provided with a light wavelength conversion member 1 consisting of a glass sheet 2 as a transparent substrate and a silicon oxide film 3 formed on the glass sheet 2 and having the silicon nanoparticles 5 dispersed therein and with a photovoltaic cell 51, and the solar battery 60 is configured so that the silicon oxide film 3 is in contact with the photovoltaic cell 51. Further, the photovoltaic cell 51 is provided with a light absorbing layer 51a of crystalline silicon etc. and electrodes 51b. This light absorbing layer 51a receives light which is incident from the antireflection film 52 side and converted in wavelength by the light wavelength conversion member 1.

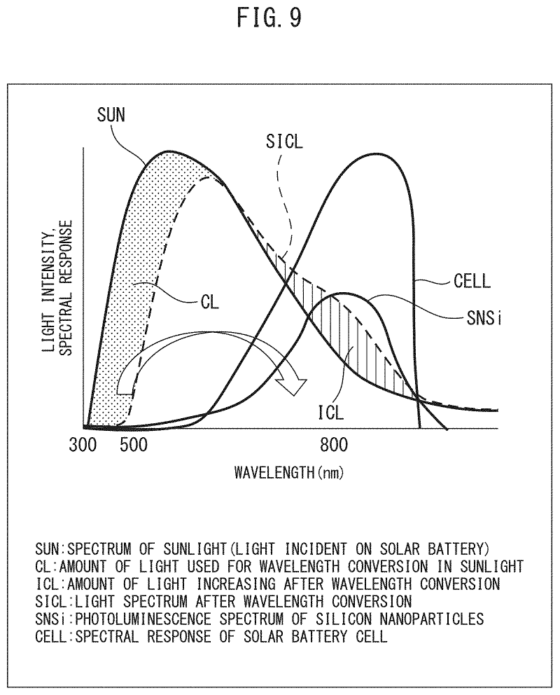

The spectrum of the incident light (sunlight) (notation SUN) and the spectrum of the light converted by the light wavelength conversion member 1 (notation SICL) are shown in FIG. 9. The spectral response of the photovoltaic cell 51 according to the present invention is shown by the notation CELL in FIG. 9. Further, the photoluminescence spectrum of the silicon nanoparticles excited by the sunlight is shown by the notation SNSi in FIG. 9.

When comparing the light spectra of the notations SUN, SICL, and CELL, the light intensity converted by the light wavelength conversion member 1 is lower compared with sunlight intensity in the wavelength region wherein the spectral response of the photovoltaic cell is low. However, the light intensity converted by the light wavelength conversion member 1 is higher in the wavelength region of the high spectral response of the photovoltaic cell. From this fact, it is learned that the light wavelength conversion member 1 converts part of the amount of sunlight in the wavelength region of the low spectral response of the photovoltaic cell (notation CL) to an amount of light in the wavelength region wherein the spectral response of the photovoltaic cell is high (notation ICL). This conversion efficiency of the light wavelength conversion member 1 is based on the photoluminescence quantum yield of the silicon nanoparticles.

In the solar spectrum (notation SUN), the wavelength region with the low spectral response of the photovoltaic cell (notation CL) is absorbed in the light wavelength conversion member 1. The light absorbed in the light wavelength conversion member 1 is re-emitted in the wavelength region with the high spectral response of the photovoltaic cell. Due to this, the solar spectrum changes to the spectrum shown by the notation SICL and the light intensity becomes higher than the sunlight intensity in the wavelength region with the high spectral response (notation ICL). This conversion efficiency of the light wavelength conversion member 1 is based on the photoluminescence quantum yield of the silicon nanoparticles.

The higher the spectral response, the higher the efficiency of generation of electric power in the corresponding wavelength region. The solar battery provided with the light wavelength conversion member of the present invention can convert light of a wavelength region of 300 nm to 500 nm with a low spectral response to light of a wavelength region of 800 nm or so with a high spectral response of the photovoltaic cell, so the output of the solar battery is improved. Further, the light wavelength conversion member of the present invention is high in the photoluminescence quantum yield in the light absorbing wavelength of the photovoltaic cell. Therefore, a photovoltaic module manufactured using the light wavelength conversion member of the present invention is improved in efficiency of generation of electric power.

In the photovoltaic module and solar battery of embodiments of the present invention, the light wavelength conversion member 1 of the present invention can convert the incident solar spectrum to correspond to the light absorption spectrum of the semiconductor composing the solar battery, so it is possible to enhance the efficiency of generation of electric power by the photovoltaic module 50 or solar battery 60.

### Examples

Below, examples will be used to explain the present invention more specifically, but the present invention is not limited to these.

The manufacturing conditions of the light wavelength conversion members of Sample Nos. 1 to 8 are shown in Table 1-1. Further, Sample Nos. 5 to 8 are invention examples manufactured by the method of manufacture of the present invention, while Sample Nos. 1 to 4 are comparative examples with respect to the present invention.

First, 5 mm square, 1 mm thick monocrystalline silicon chips were evenly arranged on a diameter 152.4 mm SiO₂ disk. This disk on which the silicon chips were placed was used as the target. The silicon/SiO₂ ratio was adjusted by the number of silicon chips. The substrate to be covered by the sputtered particles used was an SiO₂ square plate with a vertical length and horizontal length of 20 mm×20 mm and a thickness of 2 mm and with an optically polished surface.

Manufacturing Conditions of Sample Nos. 1 to 4

Sample Nos. 1 to 4 are comparative examples with respect to the present invention. Sample Nos. 1 to 3 make the substrate surfaces of the substrates face the target surfaces in parallel and set the substrates at positions close to the normal line of the targets. Sample No. 4 was manufactured by the method for placing the substrate at a position near to the target normal and inclining the substrate with respect to the normal so as to deposit the sputtered particles at an inclination. Next, the chamber was evacuated, then Ar gas 50 SCCM was introduced and the inside of the chamber was made 0.7 Pa by a pressure regulator. Sputtering was performed by applying high frequency power of 800 W to the target to form a silicon oxide film in which silicon is dispersed to a thickness of 1 μm. Further, the silicon oxide films in which Si particles were dispersed were formed without heating the substrates in Sample Nos. 1, 2, and 4 and heating the substrate to 400° C. in Sample No. 3.

The surface roughnesses of the silicon oxide films were measured by atomic force microscopy (NanoScope 5 Dimension-5000 made by Bruker) in a 15 μm×15 μm region. The measurement results of the surface roughnesses of the silicon oxide films of Sample Nos. 1 to 4 are shown in Table 1-1.

Sample Nos. 1 to No. 4 were manufactured by heat treating silicon oxide films at 800° C. in Ar or nitrogen gas (N₂) atmosphere as shown in the “First heat treatment” column of Table 1-1. The “Ar” of the column of the “Gas composition of atmosphere” in Table 1-1 indicates an atmosphere of Ar gas 100 vol %, while the “N₂” indicates an atmosphere of nitrogen gas 100 vol %. Further, in each sample, no process is performed of heat treating the silicon oxide film in an oxygen-containing atmosphere.

Manufacturing Conditions of Sample Nos. 5 to 8

Sample Nos. 5 to 8 are invention examples manufactured by the method of manufacture of the present invention. In each of Sample Nos. 1 to 4, the “first heat treatment” of Sample Nos. 1 to 4 was performed, then heat treatment was performed in an oxygen-containing atmosphere under the conditions shown in the column of “Second heat treatment”. The surface roughnesses of the silicon oxide films of Sample Nos. 5 to 8 were measured under the same conditions as Sample Nos. 1 to 4. The measurement results of these surface roughnesses are shown in Table 1-1.

Light of a wavelength of 450 nm for excitation was irradiated at the silicon nanoparticle light emitters obtained by the above manufacturing conditions. The generated photoluminescence spectrum were measured by a spectroscope (C10027-02 made by Hamamatsu Photonics). The measurement results of the photoluminescence quantum yields under the manufacturing conditions of Sample Nos. 1 to 8 are shown in Table 1-1. Further, the ESRs of Sample Nos. 1 to 8 were measured under the following measurement conditions of the electron spin resonance method (ESR).

Measurement Conditions of Electron Spin Resonance Method (ESR)

The magnetic field was modulated by radiating microwaves under the following conditions to measure the samples for ESR. The g-values and spin densities of the samples were found by simultaneous measurement of the Mn markers (Mn²⁺ in MgO).

Apparatus: JES-FE3T made by JEOL

Microwave: 9.37 GHz (frequency), central signal: 3330G

Magnetic field sweep from central signal: 100G

Conditions of modulation of magnetic field: 100 kHz (frequency), 1.6G (magnitude of modulation of magnetic field), sweep time: 60 s×20 times

Measurement temperature: room temperature

Manufacturing Conditions of Sample Nos. 9 to 14

The sizes of the silicon nanoparticles change and the fluorescence peak wavelengths change depending on the temperature of the “First heat treatment”, so the experiments were conducted under the condition of making the temperature of the “First heat treatment” to be 1000° C. For Sample Nos. 11 and 14, samples with substrate surfaces buffed by diamond paste were used.

Further, targets and substrates similar to Samples Nos. 1 to 8 were used. The method of inclination of the substrates was made one similar to Sample Nos. 1 to 8. Sample Nos. 12 to 14 are invention examples manufactured by the method of manufacture of the present invention, while Sample Nos. 9 to 11 are comparative examples with respect to the present invention. In each of Sample Nos. 12 to 14, the “First heat treatment” of Sample Nos. 9 to 11 was performed, then heat treatment was performed in an oxygen-containing atmosphere under the conditions shown in the column of “Second heat treatment”.

The manufacturing conditions of Sample Nos. 9 to 14 and the results of measurement of the photoluminescence quantum yields at the manufacturing conditions of the Sample Nos. 9 to 14 are shown in Table 1-1. Further, the photoluminescence quantum yields of Sample Nos. 9 to 14 were measured by a method similar to the measurement method of Sample Nos. 1 to 8. Further, the surface roughnesses of the silicon oxide films of Sample Nos. 9 to 14 were measured under the same conditions as Sample Nos. 1 to 4, while the ESRs of Sample Nos. 9 to 14 were measured under the measurement conditions of the electron spin resonance method explained above.

Manufacturing Conditions of Sample Nos. 15 to 39

The influence of the presence of a rough layer, the effect of the surface roughness of the substrate, the “Second heat treatment” and the composition of the ambient gas in the “Second heat treatment”, and the temperature of the “Second heat treatment” under the condition of making the “First heat treatment” temperature to be 1150° C. were investigated.

In Sample Nos. 22, 23, 35, and 36, the rough layer is formed before forming the silicon oxide film. The rough layer of these samples was formed in the following way:

Conditions for Formation of Rough Layer

The substrates of Sample Nos. 22, 23, 35, and 36 were set at positions close to the target normal and at an inclination by 40° or 60° with respect to the normal. The inside of the chamber was evacuated, then a target similar to that used for forming the silicon oxide film of Sample Nos. 1 to 8 was used to deposit the rough layer on the substrates of Sample Nos. 22, 23, 35, and 36 to the thicknesses shown in Table 1-2, without heating the substrates, while adjusting the pressure inside the chamber to 0.7 Pa by a pressure regulator and introducing 50 SCCM of Ar gas and 12.5 SCCM of O₂ gas.

Further, the sputtering was performed by applying high frequency power of 500 W to the target. The surface roughness of the silicon film formed on the rough layer was measured by a method similar to Sample Nos. 1 to 8. The measurement results were shown in Table 1-1 and Table 1-2.

Conditions for Formation of Silicon Oxide Film

Sample Nos. 15 to 39 were respectively formed with silicon oxide films in which silicon nanoparticles were dispersed under the conditions of Table 1-1 and Table 1-2. The inside of the chamber was evacuated, then the atmosphere of the inside of the chamber was made to become the gas composition shown in Table 1-2 by adjustment by a pressure regulator while introducing a total flow of 50 SCCM of Ar gas to the inside of the chamber to make the inside of the chamber 0.7 Pa. Next, without heating the substrate, the sputtering was performed by applying an high frequency power of 800 W to the target. The sputtering was performed until the thickness of the silicon oxide film in which Si particles were dispersed became 1 μm.

Further, in Sample No. 34, the method was adopted of inserting a mask (collimator) between the substrate and target to make the sputtered particles impinge on the substrate at an inclination.

The silicon oxide films in which Si particles were dispersed were heat treated under the conditions in the “First heat treatment” columns of Table 1-1 and Table 1-2 to make the Si particles in the films aggregate on a nanoscale. Further, Sample Nos. 21 and 24 to 39 were heat treated in a nitrogen- or oxygen-containing atmosphere under the conditions shown in the “Second heat treatment” columns of Table 1-1 and Table 1-2.

In the “Second heat treatment” column of Table 1-2, the heat treatment atmosphere is a mixed gas consisting of argon or nitrogen and oxygen. When oxygen is Xvol %, “Ar+Xvol % O₂” is described. For example, in Table 1-2, the entry “Ar+50 vol % O₂” indicates the heat treatment atmosphere is a mixed gas consisting of argon and oxygen with a content of 20 vol %.

Measurement of Photoluminescence Quantum Yield

The same method as in Sample Nos. 1 to 14 was used to measure the photoluminescence quantum yields of Sample Nos. 15 to 39. The results of measurement of the photoluminescence quantum yields under the manufacturing conditions of Sample Nos. 15 to 39 are shown in Table 1-2.

TABLE 1-1

| | | Rough | Silicon oxide film in which Si particles are dispersed | | | | First heat treatment | | | Second heat treatment | | | | | Photoluminescence | |
|---|---|---|---|---|---|---|---|---|---|---|---|---|---|---|---|---|
| | Inv./ | layer | Surface | Substrate | Incidence angle | | | | Gas comp. | | | Gas comp. | Spin density (cm⁻³) | | Peak | |
| Sample | Comp. | thickness | roughness | temp. | Angle | | Temp. | Time | of | Temp. | Time | of | Pb- | Pce- | wavelength | Quantum |
| No. | ex. | (μm) | (nm) | (° C.) | (°) | Method | (° C.) | (h) | atmosphere | (° C.) | (h) | atmosphere | centers | centers | (nm) | yield |
| 1 | Comp. ex. | — | 2 | Room temp. | 0 | | 800 | 2 | Ar | | | | | | No fluorescence | |
| 2 | Comp. ex. | | 2 | Room temp. | 0 | | 800 | 2 | N₂ | | | | | | No fluorescence | |
| 3 | Comp. ex. | | 2 | 400 | 0 | | 800 | 2 | N₂ | | | | | | No fluorescence | |
| 4 | Comp. ex. | | 2 | Room temp. | 40 | Inclination of substrate | 800 | 2 | Ar | | | | | | No fluorescence | |
| 5 | Invention | | 2 | Room temp. | 0 | | 800 | 2 | Ar | 600 | 1 | Air | 1.80E+16 | <1E+16 | 760 | 20 |
| 6 | Invention | | 2 | Room temp. | 0 | | 800 | 2 | N₂ | 600 | 1 | Air | 1.60E+16 | <1E+16 | 755 | 22 |
| 7 | Invention | | 2 | 300 | 0 | | 800 | 2 | N₂ | 600 | 1 | Air | 1.20E+16 | <1E+16 | 770 | 17 |
| 8 | Invention | | 2 | Room temp. | 40 | Inclination of substrate | 800 | 2 | Ar | 600 | 1 | Air | 1.50E+16 | <1E+16 | 770 | 25 |
| 9 | Comp. ex. | | 2 | Room temp. | 0 | | 1000 | 2 | Ar | | | | 3.20E+17 | 7.80E+16 | 730 | 2 |
| 10 | Comp. ex. | | 2 | Room temp. | 15 | Inclination of substrate | 1000 | 2 | Ar | | | | 1.80E+17 | 7.90E+16 | 750 | 2 |
| 11 | Comp. ex. | | 30 | Room temp. | 40 | Inclination of substrate | 1000 | 2 | Ar | | | | 8.70E+16 | 2.30E+16 | 770 | 8 |
| 12 | Invention | | 2 | Room temp. | 0 | | 1000 | 2 | Ar | 600 | 1 | Air | 2.90E+16 | <1E+16 | 740 | 28 |
| 13 | Invention | | 2 | Room temp. | 15 | Inclination of substrate | 1000 | 2 | Ar | 600 | 1 | Air | 2.50E+16 | <1E+16 | 780 | 29 |
| 14 | Invention | | 30 | Room temp. | 40 | Inclination of substrate | 1000 | 2 | Ar | 600 | 1 | Air | 2.80E+16 | <1E+16 | 790 | 37 |
| 15 | Comp. ex. | | 2 | Room temp. | 0 | | 1150 | 1 | Ar | | | | 5.70E+17 | 9.60E+16 | 780 | 3 |
| 16 | Comp. ex. | | 2 | Room temp. | 0 | | 1150 | 1 | N₂ | | | | 3.10E+17 | 1.20E+17 | 780 | 3 |
| 17 | Comp. ex. | | 2 | Room temp. | 0 | | 1150 | 1 | Air | | | | | | No fluorescence | |
| 18 | Comp. ex. | | 30 | Room temp. | 0 | Inclination of substrate | 1150 | 1 | Air | | | | | | No fluorescence | |
| 19 | Comp. ex. | | 30 | Room temp. | 0 | | 1150 | 1 | N₂ | | | | 4.20E+16 | 5.20E+16 | 790 | 6 |
| 20 | Comp. ex. | | 30 | Room temp. | 60 | Inclination of substrate | 1150 | 1 | N₂ | | | | 2.30E+16 | 1.80E+16 | 820 | 10 |

Note)
Symbol “ ” indicates no corresponding constitution or corresponding process.

TABLE 1-2

| | | Rough | Silicon oxide film in which Si particles are dispersed | | | | First heat treatment | | | Second heat treatment | | | | | Photoluminescence | |
|---|---|---|---|---|---|---|---|---|---|---|---|---|---|---|---|---|
| | Inv./ | layer | Surface | Substrate | Incidence angle | | | | Gas comp. | | | Gas comp. | Spin density (cm⁻³) | | Peak | |
| Sample | Comp. | thickness | roughness | temp. | Angle | | Temp. | Time | of | Temp. | Time | of | Pb- | Pce- | wavelength | Quantum |
| No. | ex. | (μm) | (nm) | (° C.) | (°) | Method | (° C.) | (h) | atmosphere | (° C.) | (h) | atmosphere | centers | centers | (nm) | yield |
| 21 | Comp. ex. | | 30 | Room temp. | 60 | Inclination of substrate | 1150 | 1 | N2 | 1000 | 1 | N2 | 2.50E+16 | 2.00E+16 | 810 | 10 |
| 22 | Comp. ex. | 0.1 | 7 | Room temp. | 40 | Inclination of substrate | 1150 | 1 | Ar | | | | 1.80E+16 | 2.50E+16 | 810 | 12 |
| 23 | Comp. ex. | 0.2 | 11 | Room temp. | 60 | Inclination of substrate | 1150 | 1 | Ar | | | | 2.70E+16 | 2.30E+16 | 790 | 13 |
| 24 | Comp. ex. | | 2 | Room temp. | 0 | | 1150 | 1 | Ar | 400 | 1 | Air | 4.20E+16 | 3.70E+16 | 770 | 11 |
| 25 | Comp. ex. | | 2 | Room temp. | 0 | | 1150 | 1 | N₂ | 800 | 1 | N₂ | 3.80E+16 | <1E+16 | 805 | 13 |
| | | | | | | | | | | | | +0.5 vol % O₂ | | | | |
| 26 | Comp. ex. | | 2 | Room temp. | 0 | | 1150 | 1 | N₂ | 800 | 1 | N₂ | 4.60E+16 | <1E+16 | 760 | 12 |
| | | | | | | | | | | | | +60 vol % O₂ | | | | |
| 27 | Comp. ex. | | 2 | Room temp. | 0 | | 1150 | 1 | N₂ | 1100 | 1 | Air | 8.00E+16 | <1E+16 | 750 | 8 |
| 28 | Invention | | 2 | Room temp. | 0 | | 1150 | 1 | Ar | 500 | 1 | Air | 2.80E+16 | <1E+16 | 815 | 32 |
| 29 | Invention | | 2 | Room temp. | 0 | | 1150 | 1 | Ar | 1000 | 1 | Air | 2.70E+16 | <1E+16 | 830 | 42 |
| 30 | Invention | | 2 | Room temp. | 0 | | 1150 | 1 | N₂ | 800 | 1 | N₂ | 2.50E+16 | <1E+16 | 825 | 38 |
| | | | | | | | | | | | | +1 vol % O₂ | | | | |
| 31 | Invention | | 2 | Room temp. | 0 | | 1150 | 1 | N₂ | 800 | 1 | Ar | 1.80E+16 | <1E+16 | 795 | 45 |
| | | | | | | | | | | | | +50 vol % O₂ | | | | |
| 32 | Invention | | 30 | Room temp. | 0 | | 1150 | 1 | N₂ | 600 | 1 | Air | 1.20E+16 | <1E+16 | 810 | 48 |
| 33 | Invention | | 30 | Room temp. | 40 | Inclination of substrate | 1150 | 1 | N₂ | 600 | 1 | Air | <1E+16 | <1E+16 | 830 | 50 |
| 34 | Invention | | 30 | Room temp. | 40 | Collimator | 1150 | 1 | N₂ | 600 | 1 | Air | <1E+16 | <1E+16 | 830 | 41 |
| 35 | Invention | 0.1 | 7 | Room temp. | 40 | Inclination of substrate | 1150 | 1 | Ar | 600 | 1 | Air | <1E+16 | <1E+16 | 820 | 47 |
| 36 | Invention | 0.2 | 11 | Room temp. | 60 | Inclination of substrate | 1150 | 1 | Ar | 600 | 1 | Air | <1E+16 | <1E+16 | 850 | 55 |
| 37 | Invention | | 11 | Room temp. | 60 | Inclination of substrate | 1150 | 1 | N₂ | 600 | 1 | Air | <1E+16 | <1E+16 | 840 | 48 |
| 38 | Invention | | 47 | Room temp. | 40 | Inclination of substrate | 1150 | 1 | N₂ | 600 | 1 | Air | 1.50E+16 | <1E+16 | 885 | 47 |
| 39 | Comp. ex. | | 58 | Room temp. | 40 | Inclination of substrate | 1150 | 1 | N₂ | 600 | 1 | Air | 3.60E+16 | <1E+16 | 940 | 12 |

Note)
Symbol “ ” indicates no corresponding constitution or corresponding process.

In Sample Nos. 17 and 18 of the comparative examples, it is learned that fluorescence occurs if using oxygen-containing gas in the “First heat treatment”.

If comparing Sample Nos. 15, 16, and 19 to 27 of the comparative examples and Sample Nos. 28 to 38 of the invention examples for manufacturing conditions and results of measurement of photoluminescence quantum yields, it will be understood that by performing heat treatment in a nonoxidizing gas atmosphere, then performing heat treatment in an oxygen-containing atmosphere, the photoluminescence quantum yield is improved by 30% or more in each case.

In each of the samples of the invention examples, the spin density of the P_{b}-center was 3×10¹⁶/cm³ or less and the spin density of the P_{ce}-center was 1×10¹⁶/cm³ or less. As opposed to this, in each of the samples of the comparative examples, no fluorescence occurred or the fluorescence was weak. That is, in the samples of the comparative examples where fluorescence occurred, the spin density of the P_{b}-center was 3×10¹⁶/cm³ or more and/or the spin density of the P_{ce}-center was 1×10¹⁶/cm³ or more.

Measurement Results of Photoluminescence Spectra

FIG. 7 shows the results of measurement of photoluminescence (PL) intensity obtained from Sample Nos. 16, 20, and 39 of the comparative examples and Sample Nos. 32, 33, 37, and 38 of the invention examples when irradiating 450 nm excitation light on the samples. As shown in FIG. 7, it is learned that light wavelength conversion members heat-treated in a nonoxidizing atmosphere, then heat-treated in an oxygen-containing atmosphere are higher in emission intensities, in particular are much higher in them at wavelengths giving the strongest photoluminescence intensities, compared with the comparative examples in all wavelength regions where photoluminescence spectra are detected.

Further, as shown in FIG. 7, the maximum values of the PL intensities of Sample Nos. 33, 37, and 38 of the invention examples are higher than the maximum value of the PL intensity of Sample No. 39 of the comparative example. Sample No. 39 has an arithmetic average roughness Ra of the silicon oxide film surface of over 50 nm, so probably its PL intensity remarkably decreased. Further, the maximum value of the PL intensity of Sample No. 37 of the invention example is higher than the maximum value of the PL intensity of Sample Nos. 33 and 38 of the invention examples. Sample No. 37 has an arithmetic average roughness Ra of the silicon oxide film surface smaller than Invention Example No. 38. In this way, to raise the maximum value of the PL intensity, the suitable arithmetic average roughness Ra of the silicon oxide film surface is less than 30 nm.

Further, the particle sizes of the silicon nanoparticles were estimated based on the descriptions in PTLs 1 and 9 from the PL spectrum of FIG. 7. The PL of the samples shown in FIG. 7 are 650 nm to 1000 nm, so the sizes of the silicon nanoparticles in the silicon oxide films of the samples shown in FIG. 7 were estimated to be 2.5 nm to 5 nm in range.

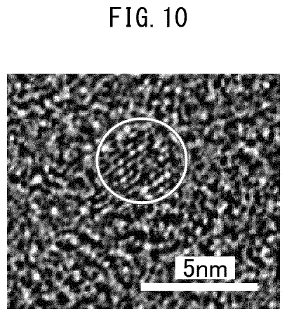

In actuality, when examining the cross-section of the silicon oxide film in which Si particles are dispersed of Sample No. 37 by a transmission electron microscope (TEM), it was confirmed that the silicon nanoparticles in the silicon oxide film of Sample No. 37 had a silicon particle size of about 3 nm (FIG. 10).

Measurement Results of Rate of Improvement of Output of Solar Battery

The rate of improvement of output in the case of using a solar battery of the structure shown in FIG. 6 and installing the light wavelength conversion member of the present invention was investigated. The outputs of a solar battery in the case using a monocrystalline silicon photovoltaic cell as the photovoltaic cell 51 and placing just a glass substrate 2 on the top surface of the photovoltaic cell and in the case of placing a light wavelength conversion member 1 structured by a silicon oxide film 3 in which silicon nanoparticles 5 are dispersed formed on a glass substrate 2 on it were measured using a solar simulator (ES-155S1 made by San-Ei Electric). Further, unlike sunlight, with a solar simulator, there is little light incident with an inclination, so in this measurement, no antireflection film 52 is coated.

Compared with the output of a solar battery of a structure in which no silicon oxide film 3 in which silicon nanoparticles 5 are dispersed is provided and in which only a glass substrate 2 is set, in Sample No. 1 (comparative example), a −2% output and in Sample Nos. 7 and 33 (invention examples), 2% and 8% improvements in output were seen. In this way, a solar battery manufactured using the light wavelength conversion member of the present invention is improved in efficiency of generation of electric power.

From the above results, it is shown that, according to the present invention, a light wavelength conversion member with higher light emitting intensities at various wavelengths can be easily produced relatively inexpensively without lowering the productivity. Further, it is shown that according to the present invention, the efficiency of generation of electric power of a solar battery and photovoltaic module is improved corresponding to the light absorption spectra of the semiconductor composing the solar battery module.

### INDUSTRIAL APPLICABILITY

The light wavelength conversion member according to the present invention can be suitably used for a photovoltaic module or a solar battery.

### REFERENCE SIGNS LIST

1 light wavelength conversion member
2 smooth substrate
3 silicon oxide film
3a pore or void
3b rough layer
4 Si particles
5 silicon nanoparticles
6 silicon nanoparticles
10 target
10′ first target
10″ second target
11 silicon chip
20 light guide plate
21 blue LED
22 light emitter
23 reflector
30, 40 backlight
50 photovoltaic module
51 photovoltaic cell
60 solar battery

1. A light wavelength conversion member comprising a substrate and a silicon oxide film in which silicon nanoparticles are dispersed,
wherein the silicon oxide film is superposed on one surface of the substrate, directly or through another layer,
wherein the silicon oxide film has a spin density of 1×10¹⁶/cm³ or less at an electron spin resonance signal of g-value of 1.9980±0.0010 and a spin density 3×10¹⁶/cm³ or less at g-value of 2.0030±0.0010 when measuring the silicon oxide film by way of an electron spin resonance method.

2. The light wavelength conversion member according to claim 1, wherein the silicon oxide film in which silicon nanoparticles are dispersed has an arithmetic average roughness Ra of 5 nm to 50 nm.

3. The light wavelength conversion member according to claim 1, wherein the silicon oxide film is superposed over a rough layer formed on one surface of the substrate and the rough layer contains at least one of oxygen and nitrogen, contains silicon, and has a thickness of 0.1 μm to 0.3 μm.

4. A solar battery including the light wavelength conversion member according to a claim 1 placed on a light receiving surface side.

5. A photovoltaic module including the light wavelength conversion member according to claim 1 placed on a light receiving surface side.

6. A method for producing a light wavelength conversion member comprising the steps of:
forming a silicon oxide film on a substrate by way of sputtering, a temperature of the substrate being made to be 300° C. or less,
dispersing silicon in the silicon oxide film, then heat treating the silicon oxide film in a nonoxidizing atmosphere at a temperature range of from 800° C. to 1150° C., and
heat treating the silicon oxide film in an oxygen-containing atmosphere at a temperature range of from 500° C. to 1000° C.

7. The method for producing a light wavelength conversion member according to claim 6, wherein in the step of sputtering, an incidence angle of sputtered particles from a target to the substrate surface is made to be 10° to 80° with respect to a normal of the substrate.

8. The method for producing a light wavelength conversion member according to claim 6, wherein, in the step of sputtering, the substrate surface is inclined by 10° to 80° with respect to a directly facing target surface to control an incidence direction of sputtered particles from the target.

9. The method for producing a light wavelength conversion member according to claim 6, wherein a target in which silicon and silicon oxide are mixed in a sputtered area is sputtered to disperse silicon in the silicon oxide film.

10. The method for producing a light wavelength conversion member according to claim 7, wherein an incidence direction of sputtered particles from a target consisting of silicon oxide or a target in which silicon and silicon oxide are mixed in a sputtered area is made to be 10° to 80° with respect to a normal of the substrate,
wherein a temperature of the substrate is made to be 300° C. or less, and
wherein the step of sputtering is conducted in an atmosphere containing at least one of oxygen and nitrogen to deposit a rough layer of a 0.1 μm to 0.3 μm thickness, then the silicon oxide film is formed on the substrate.

11. The method for producing a light wavelength conversion member according to claim 10, wherein the rough layer is deposited in the atmosphere containing argon gas and at least one of oxygen and nitrogen, and
wherein the total pressure of the atmosphere is 0.3 Pa to 1.5 Pa, and the total of the oxygen partial pressure and nitrogen partial pressure is 10% to 50% with respect to the total pressure of the atmosphere.

12. The method for producing a light wavelength conversion member according to claim 6, wherein the step of heat treating in the oxygen-containing atmosphere is carried out in an oxygen-containing atmosphere containing a concentration of 1 vol % to 50 vol % of oxygen.

13. The light wavelength conversion member according to claim 2, wherein the silicon oxide film is superposed over a rough layer formed on one surface of the substrate and the rough layer contains at least one of oxygen and nitrogen, contains silicon, and has a thickness of 0.1 μm to 0.3 μm.

14. A solar battery including the light wavelength conversion member according to claim 2 placed on a light receiving surface side.

15. A solar battery including the light wavelength conversion member according to claim 3 placed on a light receiving surface side.

16. A photovoltaic module including the light wavelength conversion member according to claim 2 placed on a light receiving surface side.

17. A photovoltaic module including the light wavelength conversion member according to claim 3 placed on a light receiving surface side.

18. The method for producing a light wavelength conversion member according to claim 7, wherein, in the step of sputtering, the substrate surface is inclined by 10° to 80° with respect to a directly facing target surface to control an incidence direction of sputtered particles from the target.

19. The method for producing a light wavelength conversion member according to claim 7, wherein a target in which silicon and silicon oxide are mixed in a sputtered area is sputtered to disperse silicon in the silicon oxide film.

20. The method for producing a light wavelength conversion member according to claim 7, wherein an incidence direction of sputtered particles from a target comprising silicon oxide or a target in which silicon and silicon oxide are mixed in a sputtered area is made to be 10° to 80° with respect to a normal of the substrate,
wherein a temperature of the substrate is made to be 300° C. or less, and
wherein the step of sputtering is conducted in an atmosphere containing at least one of oxygen and nitrogen to deposit a rough layer of a 0.1 μm to 0.3 μm thickness, then the silicon oxide film is formed on the substrate.
